(19) United States
(12) Patent Application Publication
(10) Pub. No.: US 2020/0309858 A1
(43) Pub. Date: Oct. 1, 2020

(54) LIFETIME PREDICTION DEVICE, LIFETIME PREDICTION METHOD, AND STORAGE MEDIUM

(71) Applicant: HONDA MOTOR CO., LTD., Tokyo (JP)

(72) Inventor: Koji Nakanishi, Wako-shi (JP)

(21) Appl. No.: 16/823,372

(22) Filed: Mar. 19, 2020

(30) Foreign Application Priority Data
Mar. 27, 2019 (JP) 2019-059874

(51) Int. Cl. G01R 31/367; H01M 10/42

(52) U.S. Cl. CPC G01R 31/367; H01M 2220/20; H01M 10/4285

(57) ABSTRACT

A lifetime prediction device includes: an acquirer configured to acquire information regarding a use state of a battery member mounted on a vehicle; and a predictor configured to predict a lifetime of the battery member to be reused at the time of reuse according to the use state.

### CROSS-REFERENCE TO RELATED APPLICATION

This application claims priority to and the benefit from Japanese Patent Application No. 2019-059874, filed on Mar. 27, 2019, the contents of which are hereby incorporated by reference into the present application.

### BACKGROUND OF THE INVENTION

### Field of the Invention

The present invention relates to a lifetime prediction device, a lifetime prediction method, and a storage medium.

### Description of Related Art

Batteries mounted in electric automobiles can also be sufficient for use for other applications even when the batteries cannot exert sufficient on-board performance because of degrading. Accordingly, after on-board batteries degrade, the degraded batteries can conceivably be reused by mounting the batteries on other products. Regarding battery reuse, there is a technology for determining whether a battery is able to be reused (for example, see Japanese Unexamined Patent Application, First Publication No. 2018-156768).

Regarding battery reuse, it can be determined whether to reuse the battery. However, when a battery is reused for another product, indicators for determining how much battery performance is exerted have not been introduced. Therefore, it is difficult for a person who wants to reuse a battery to determine a battery which is good to be reused.

The present invention is devised in view of such circumstances and an objective of the present invention is to provide a lifetime prediction device, a lifetime prediction method, and a storage medium capable of providing a standard for selecting a battery to be reused.

A lifetime prediction device, a lifetime prediction method, and a storage medium according to the present invention adopt the following configurations.

(1) According to an aspect of the present invention, a lifetime prediction device includes: an acquirer configured to acquire information regarding a use state of a battery member mounted on a vehicle; and a predictor configured to predict a lifetime of the battery member to be reused at the time of reuse according to the use state.

(2) In the aspect (1), the predictor is configured to predict the lifetime according to a type of a target product in which the battery member is reused.

(3) In the aspect (1) or (2), the acquirer is configured to acquire information regarding a use state at the time of reuse of the battery member, and the predictor configured to predict the lifetime according to the information regarding the use state at the time of reuse of the battery member.

(4) In the aspects (1) to (3), the information regarding the use state of the battery member is information according to information collected in the vehicle.

(5) In the aspects (1) to (4), the battery member is at least one of a battery and an accessory component of the battery.

(6) In the aspect (5), the accessory component is at least one of a cooling fan, a current sensor, a voltage sensor, a temperature sensor, a battery calculation device, a contactor, a converter, and a fuse.

(7) In the aspects (1) to (6), the predictor is configured to predict the lifetime by inputting information regarding a use state of the battery member to a model obtained through machine learning.

(8) In the aspect (7) the lifetime prediction device further include a generator configured to generate the model through machine learning.

(9) According to another aspect of the present invention, there is provided a lifetime prediction method causing a computer: to acquire information regarding a use state of a battery member mounted on a vehicle; and to predict a lifetime of the battery member to be reused at the time of reuse according to the use state.

(10) According to still another aspect of the present invention, a computer-readable non-transitory storage medium stores a program causing a computer: to acquire information regarding a use state of a battery member mounted on a vehicle; and to predict a lifetime of the battery member to be reused at the time of reuse according to the use state.

According to the aspects (1) to (10), it is possible to provide a standard for selecting a battery to be reused.

### BRIEF DESCRIPTION OF THE DRAWINGS

FIG. 1 is a diagram showing an example of an overall configuration of a lifetime prediction system in which a lifetime prediction device according to an embodiment is used.

FIG. 2 is a block diagram showing an example of the lifetime prediction system in which the lifetime prediction device according to an embodiment is used.

FIG. 3 is a diagram showing an example of a configuration of a vehicle.

FIG. 4 is a diagram showing an example of battery use state collection data.

FIG. 5 is a graph showing a temporal change of a current value.

FIG. 6 is a diagram showing an example of reuse battery use state collection data.

FIG. 7 is a diagram showing an example of battery use state data.

FIG. 8 is a diagram showing an example of reuse battery use state data.

FIG. 9 is a flowchart showing an example of a flow of a process performed in the lifetime prediction device.

FIG. 10 is a flowchart showing an example of a flow of a process performed in the lifetime prediction device.

FIG. 11 is a diagram showing an example of a production process of a lifetime prediction model.

### DETAILED DESCRIPTION OF THE INVENTION

Hereinafter, embodiments of a lifetime prediction device, a lifetime prediction method, and a storage medium according to the present invention will be described with reference to the drawings. In the following description, a vehicle 10 is assumed to be an electric automobile, but the vehicle 10 may be a vehicle on which a battery (a secondary cell) supplying power for travel is mounted or may be a hybrid automobile or a fuel cell vehicle.

### [Overall Configuration]

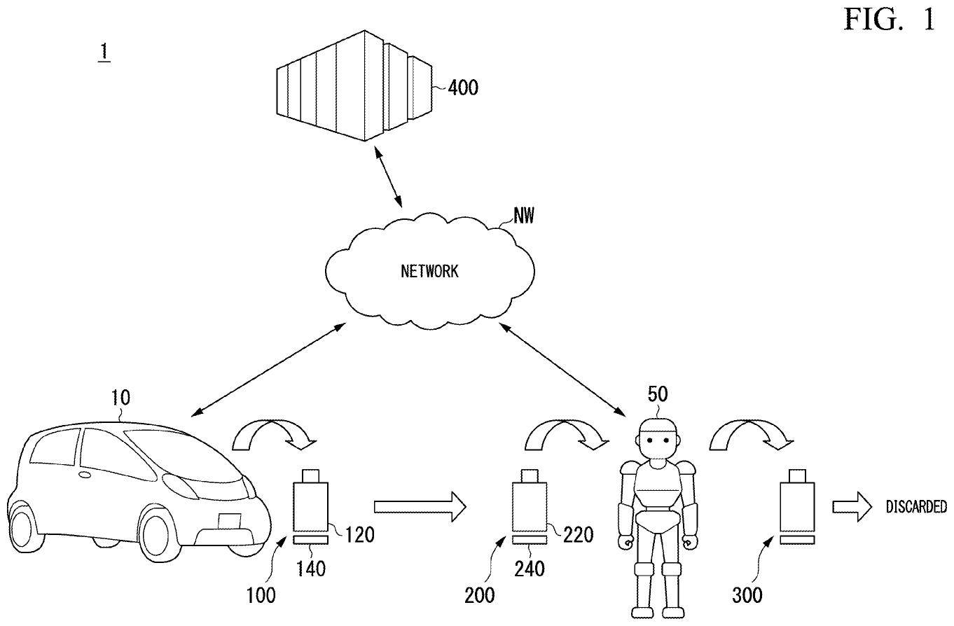

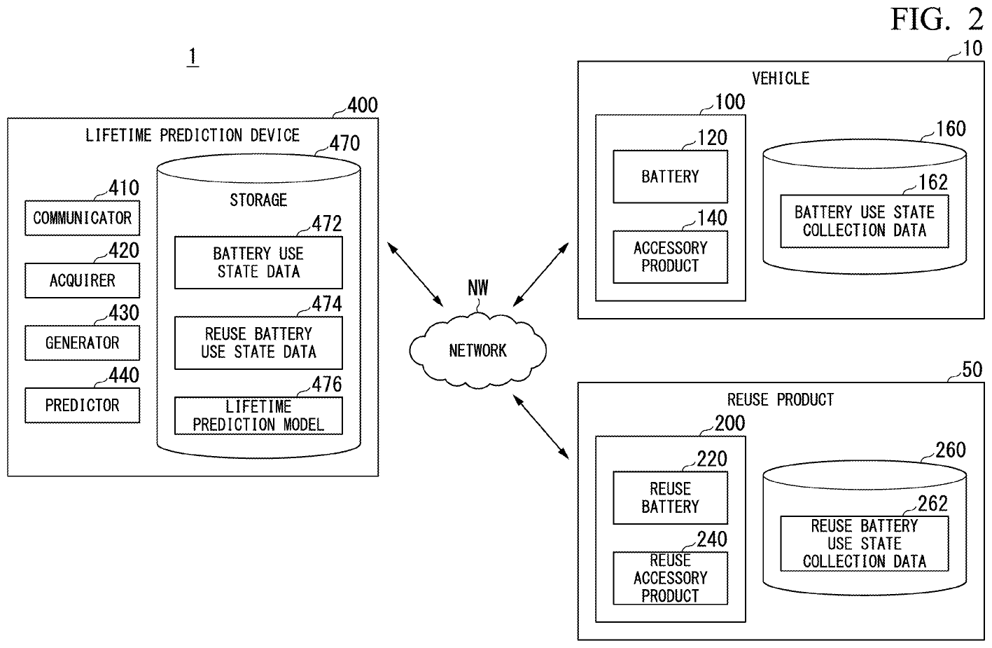

FIG. 1 is a diagram showing an example of an overall configuration of a lifetime prediction system 1 in which a lifetime prediction device 400 according to an embodiment is used. FIG. 2 is a block diagram showing an example of the lifetime prediction system 1 in which the lifetime prediction device 400 according to an embodiment is used. A battery member 100 mounted on the vehicle 10 shown in FIG. 1 degrades in accordance with use, for example, when the battery member 100 is used for a long time. When the battery member 100 degrades and fails, the battery member 100 is repaired, for example. However, when the battery member 100 further degrades, a charging capacity of a battery 120 degrades and on-board performance is not sufficiently exerted.

Accordingly, the degraded battery member 100 is mounted as a reuse battery member 200 for reuse on a reuse product 50 or the like which is a product for which the battery member 100 that has necessary performance, for example, a charging capacity lower than the vehicle 10, is reused. The lifetime prediction system 1 is a system in which a lifetime of the reuse battery member 200 is predicted when the battery member 100 mounted on the vehicle 10 is reused and mounted as the reuse battery member 200 on a reuse product.

The battery member 100 includes the battery 120 and an accessory component 140. For example, when at least one of the battery 120 and the accessory component 140 does not sufficiently exert a function as the battery member 100 mounted on the vehicle 10, the battery member 100 is reused as the reuse battery member 200.

When the reuse battery member 200 also degrades and fails in the reuse product 50, the reuse battery member is repaired, for example. However, when the reuse battery member 200 mounted on the reuse product 50 further degrades and the reuse battery member 200 cannot sufficiently exert a function necessary for the reuse product 50, the reuse battery member 200 becomes a discarded target as a discarded battery member 300, for example. Batteries which are discarded targets, such as cells or rare metals when usable cells remain, may also be used as recycled products. Examples of the reuse product 50 include a stationary battery member which is stationary in a charging station or a home, a robot, a forklift, and a cart which is used in a golf course. In the following description, for example, a case of degradation or the like of the battery member 100 degrades is equal to a case of degradation or the like of the battery 120 or the accessory component 140. For example, a case of degradation a lifetime, or the like of the reuse battery member 200 is equal to a case of degradation, a lifetime, or the like of a reuse battery 220 or a reuse accessory component 240.

As shown in FIGS. 1 and 2, the lifetime prediction system 1 includes the vehicle 10, the reuse product 50, and the lifetime prediction device 400. The lifetime prediction device 400 predicts a lifetime of the reuse battery member 200 mounted on the reuse product 50. The lifetime prediction device 400 selects the reuse battery member 200 mounted on the reuse product 50 based on the predicted lifetime.

The vehicle 10 and the lifetime prediction device 400 communicate with each other via a network NW. Similarly, the reuse product 50 and the lifetime prediction device 400 communicate with each other via the network NW. Examples of the network NW include the Internet, a wide area network (WAN), a local area network (LAN), a provider device, and a wireless base station.

### [Vehicle 10]

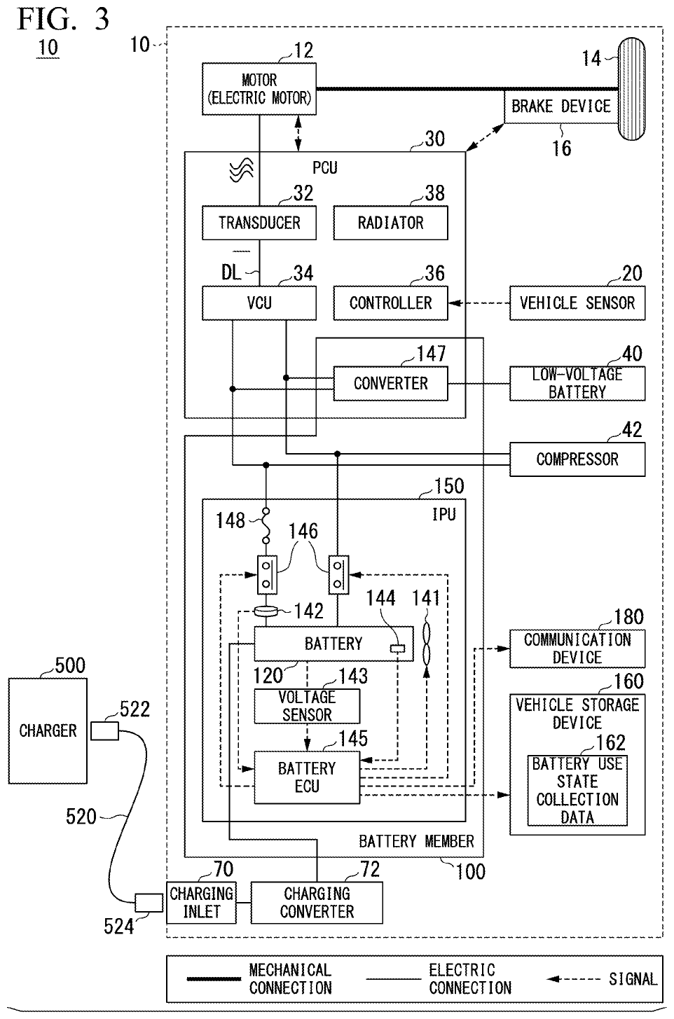

FIG. 3 is a diagram showing an example of a configuration of the vehicle 10. As shown in FIG. 3, the vehicle 10 includes, for example, a motor 12, a driving wheel 14, a brake device 16, a vehicle sensor 20, a power control unit (PCU) 30, a charging inlet 70, a charging converter 72, a battery member 100, a vehicle storage device 160, and a communication device 180.

The motor 12 is, for example, a three-phase AC motor. A rotor of the motor 12 is connected to the driving wheel 14. The motor 12 outputs motive power to the driving wheel 14 using electric power to be supplied. The motor 12 generates power using kinetic energy of a vehicle at the time of deceleration of the vehicle.

The brake device 16 includes, for example, a brake caliper, a cylinder that transmits a hydraulic pressure to the brake caliper, and an electric motor that generates the hydraulic pressure to the cylinder. The brake device 16 may include a mechanism that transmits a hydraulic pressure generated by operating a brake pedal to the cylinder via a master cylinder as a backup. The brake device 16 is not limited to the above-described configuration and may be an electronic control type hydraulic brake device that transmits a hydraulic pressure of the master cylinder to the cylinder.

The vehicle sensor 20 includes an accelerator opening sensor, a vehicle speed sensor, and a brake depression amount sensor. The accelerator opening sensor is fitted in an accelerator pedal that receives an acceleration instruction from a driver, detects an operation amount of the accelerator pedal, and outputs the operation amount as an acceleration opening to a controller 36. The vehicle speed sensor includes, for example, a speed calculator and a vehicle wheel speed sensor fitted in each vehicle wheel, integrates the vehicle wheel speeds detected by the vehicle wheel speed sensors, derive a speed of the vehicle (vehicle speed), and outputs the vehicle speed to the controller 36. The brake depression amount sensor is fitted in a brake pedal, detects an operation amount of the brake pedal, and outputs the operation amount as a brake depression amount to the controller 36.

The PCU 30 includes, for example, a transducer 32, a voltage control unit (VCU) 34, the controller 36, and a radiator 38. These constituent elements configured as a bundle of the PCU 30 are merely exemplary. The constituent elements may be disposed in a distributed manner.

The transducer 32 is, for example, an AC-DC converter. A direct-current side terminal of the transducer 32 is connected to a direct-current link DL. The battery 120 is connected to the direct-current link DL via the VCU 34. The transducer 32 converts an alternating current generated by the motor 12 into a direct current and outputs the direct current to the direct-current link DL.

The VCU 34 is, for example, a DC-DC converter. The VCU 34 boosts power supplied from the battery 120 and outputs the boosted power to the direct-current link DL.

The controller 36 includes, for example, a motor controller, a brake controller, and a battery VCU controller. The motor controller, the brake controller, and the battery VCU controller may be substituted with separate control devices, for example, control devices such as a motor electronic control unit (ECU), a brake ECU, and a battery VCU ECU.

The motor controller controls the motor 12 based on an output of the vehicle sensor 20. The brake controller controls the brake device 16 based on an output of the vehicle sensor 20. The VCU 34 raises a voltage of the direct-current link DL in accordance with an instruction from the battery VCU controller.

A low-voltage battery 40 is, for example, a battery that supplies electricity mainly for vehicle control, auxiliary machine operation, or the like. A specified voltage of the low-voltage battery 40 is a voltage lower than a specified voltage of the battery 120. A compressor 42 is, for example, a device that supplies a compressed air to an air conditioner provided in the vehicle 10. The compressor 42 is connected to the battery 120 and operates with electricity supplied by the battery 120.

The charging inlet 70 is provided to face the outside of the body of the vehicle 10. The charging inlet 70 is connected to a charger 500 via a charging cable 520. The charging cable 520 includes a first plug 522 and a second plug 524. The first plug 522 is connected to the charger 500 and the second plug 524 is connected to the charging inlet 70. Electricity supplied from the charger 500 is supplied to the charging inlet 70 via the charging cable 520.

The charging cable 520 includes a signal cable attached to a power cable. The signal cable relays communication between the vehicle 10 and the charger 500. Accordingly, a power connector and a signal connector are provided in each of the first plug 522 and the second plug 524.

The charging converter 72 is provided between the battery 120 and the charging inlet 70. The charging converter 72 converts a current introduced from the charger 500 via the charging inlet 70, for example, an alternating current, into a direct current. The charging converter 72 outputs the converted direct current to the battery 120.

The battery member 100 includes the battery 120 and the accessory component 140, as shown in FIG. 2. The accessory component 140 is a generic term for a cooling fan 141, a current sensor 142, a voltage sensor 143, a temperature sensor 144, a battery ECU 145, a contactor 146, a converter 147, and a fuse 148 shown in FIG. 3. The battery member 100 includes an intelligent power unit (hereinafter referred to as an IPU) 150. The IPU 150 includes the battery 120, the cooling fan 141, the current sensor 142, the voltage sensor 143, the temperature sensor 144, the battery ECU 145, the contactor 146, and the fuse 148. The IPU 150 includes a case member (not shown) and each member of the IPU 150 is accommodated in the case member. The battery ECU 145 is an example of a battery calculation device according to the present invention.

The battery 120 is, for example, a secondary cell such as a lithium ion battery. The battery 120 stores power introduced from the external charger 500 of the vehicle 10 and performs discharging for traveling of the vehicle 10. The cooling fan 141 rotates a vane member based on a control signal output by the battery ECU 145. The cooling fan 141 cools each device in the case of the IPU 150 by rotating the vane member.

The current sensor 142 is provided between the battery 120 and the VCU 34 and detects a current value of electricity supplied by the battery 120. The current sensor 142 outputs the detected current value to the battery ECU 145. The voltage sensor 143 is provided in the battery 120 and detects a voltage of the electricity supplied by the battery 120. The voltage sensor 143 outputs the detected voltage to the battery ECU 145. The temperature sensor 144 is fitted in, for example, the battery 120 and detects a temperature of the battery 120. The temperature sensor 144 outputs the detected temperature of the battery 120 to the battery ECU 145.

The battery ECU 145 is realized, for example, by causing a hardware processor such as a central processing unit (CPU) to execute a program (software). Some or all of the constituent elements may be realized by hardware (a circuit unit including circuitry) such as a large scale integration (LSI), an application specific integrated circuit (ASIC), a field-programmable gate array (FPGA), or a graphics processing unit (GPU) or may be realized by software and hardware in cooperation. The program may be stored in advance in a storage device (a storage device including a non-transitory storage medium) such as a hard disk drive (HDD) or a flash memory or may be stored in a detachably mountable storage medium (a non-transitory storage medium) such as a DVD, a CD-ROM, or the like so that the storage medium is mounted on a drive device to be installed.

The battery ECU 145 performs operation control of the cooling fan 141 or opening or closing control of the contactor 146 based on each piece of information output by the current sensor 142, the voltage sensor 143, and the temperature sensor 144 or other information. The battery ECU 145 has a clocking function and measures a current time or a time after the battery member 100 is mounted on the vehicle 10. The battery ECU 145 calculates a state of charge (SOC) or a state of health (SOH) of the battery 120 based on each piece of information output by the current sensor 142, the voltage sensor 143, and the temperature sensor 144, a time measured by the clocking function, or the like. The battery ECU 145 stores information regarding the calculated SOC or SOH in the vehicle storage device 160 or outputs the information to the communication device 180, as necessary. The battery 120 calculates and collects an uptime of the battery 120 and the number of years elapsed after the battery 120 is mounted on the vehicle 10 (hereinafter referred to as elapsed years) based on a clocking result by the clocking function. The battery 120 stores the collected uptime and elapsed years in the vehicle storage device 160.

The battery ECU 145 monitors and collects each piece of information regarding the current of the battery 120 output by the current sensor 142, the voltage of the battery 120 output by the voltage sensor 143, and the temperature of the battery 120 output by the temperature sensor 144. The battery ECU 145 stores the collected information as battery use state collection data 162 shown in FIG. 2 in the vehicle storage device 160.

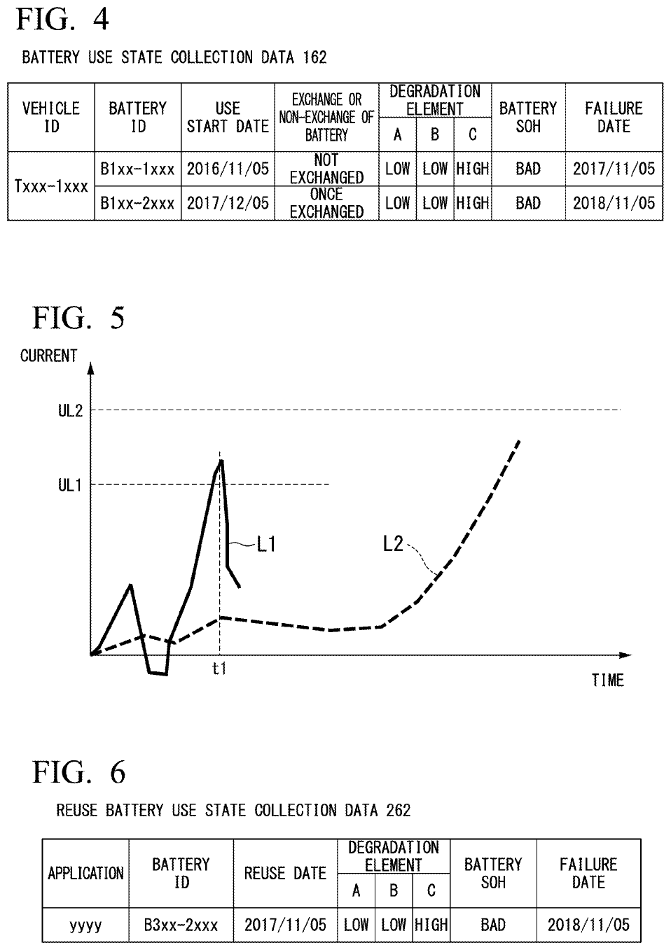

FIG. 4 is a diagram showing an example of the battery use state collection data 162. As shown in FIG. 4, the battery use state collection data 162 includes items such as a vehicle ID, a battery ID, a use start date, exchange or non-exchange of a battery, a degradation element, a battery SOH, and a failure date. The vehicle ID is a number that is given to each vehicle to identify a plurality of individual vehicles and the battery ID is a number that is given to each battery to identify a plurality of individual batteries.

The use start date is a date on which the battery member 100 including the battery 120 is mounted on the vehicle 10 and the battery member 100 starts to be used. The exchange or non-exchange of the battery is an item that indicates whether the battery member 100 is exchanged (repaired) in the vehicle 10 and indicates the number of exchanges when the battery member 100 is exchanged. The degradation element is an item that indicates an element degrading the battery 120 and the accessory component 140 in the battery member 100.

There are various factors which are degradation elements degrading the battery member 100. For example, there are factors such as a temperature, a charge or discharge depth, a voltage current, a current value, and an uptime of the battery 120 and elapsed years of use of the battery member 100. For example, when the temperature of the battery 120 is high, when the charge or discharge depth is deep, when the voltage value or the current value is large, or when the uptime or the elapsed years of the battery member 100 are long, the degree of degradation of each battery 120 or accessory component 140 increases. Examples of the degradation elements include “A,” “B,” and “C” when one or two or more of these factors are collected for each of the battery 120 and the accessory component 140. A degradation state of the battery member 100 may be collected, for example, from the perspective of two factors of an element during an uptime and an element of a vehicle's lifetime. The degradation state of the battery member 100 may be expressed collectively as in the following (1), for example.

Degradation state of battery member 100=f(temperature, charge or discharge depth, voltage value, current value, an uptime, elapsed years) (1)

For example, a current value is used as an example of collection from the perspective of two factors of an element during an uptime and an element of a vehicle's lifetime in the description. FIG. 5 is a graph showing a temporal change of a current value. As shown in FIG. 5, a first line L1 indicates a temporal change of a measured value of a current and a second line L2 indicates a temporal change of an average current. The average current is obtained by dividing an integrated current by an uptime.

In a change in the current indicated by the first line L1, the first line L1 mostly does not exceed a measured value use upper limit UL1. Meanwhile, a degradation state of the battery 120 is low. Near time t1, the current value exceeds the measured value use upper limit UL1. Meanwhile, degradation of the battery 120 increases. The battery ECU 145 records, for example, a time at which the current value exceeds the measured value use upper limit UL1 (a cumulative overtime) and a maximum current value and specifies, for example, a magnitude of the degradation elements of the battery 120 based on the cumulative overtime and the maximum current value.

The average current indicated by the second line L2 increases toward the average value use upper limit UL2 over time. The battery ECU 145 specifies, for example, a magnitude of the degradation elements of the battery 120 according to whether the average current exceeds the average value use upper limit UL2. For example, when the average current exceeds the average value use upper limit UL2, the degradation elements of the battery 120 are set to be large. The average value use upper limit is obtained by dividing an integrated current by a total time. The total time is the sum of the uptime and an idle time of the battery 120.

The battery SOH is an item indicating a SOH of the battery 120 when the battery 120 is detached from the vehicle 10. The failure date is a date on which the battery 120 fails. In the embodiment, when the battery 120 mounted on the vehicle 10 fails, the battery 120 is assumed to be exchanged. A timing at which the battery 120 is exchanged is a timing at which the battery 120 fails and a timing at which the battery 120 is detached from the vehicle for exchange despite no failure. When the battery 120 is detached from the vehicle for exchange despite no failure, the failure date indicates “none.”

The battery ECU 145 associates each piece of monitored data with failure of the battery 120 as a database when the battery 120 fails or the battery 120 which has not failed is detached from the vehicle 10. In this way, the battery ECU 145 generates the battery use state collection data 162 shown in FIG. 4 and outputs the battery use state collection data 162 to the communication device 180.

The battery ECU 145 associates a degradation pattern of the degradation element with exchange of the battery member 100, extracts a specific degradation pattern, and sets the specific degradation pattern as a use state of the battery member 100. For example, when a pattern of the same degradation element appears in one vehicle 10 and the battery member 100 is exchanged, the pattern of the degradation element may be extracted as a specific degradation pattern.

The contactor 146 is a device that is provided between the battery 120 and the VCU 34. The contactor 146 prevents an excessive current from being supplied from the battery 120. The converter 147 drops the voltage of the electricity supplied by the battery 120 to supply the electricity of the battery 120 to the low-voltage battery 40. The fuse 148 is provided between the battery 120 and the VCU 34 and prevents an excessive current from being supplied from the battery 120 at the time of short-circuiting.

The vehicle storage device 160 is realized by, for example, a storage device such as an HDD or a flash memory included in, for example, the battery ECU 145. The vehicle storage device 160 stores, for example, various kinds of information such as the current, the voltage, the temperature, and the SOH of the battery 120 collected and calculated by the battery ECU 145 as the battery use state collection data 162.

The communication device 180 includes a wireless module for connection to a cellular network or a Wi-Fi network. For example, the communication device 180 transmits the battery use state collection data 162 such as the current value, the voltage value, the temperature, and the SOH of the battery 120 output by the battery member 100 to the lifetime prediction device 400 via the network NW shown in FIG. 1.

### [Reuse Product 50]

As shown in FIG. 2, the reuse product 50 includes, for example, the reuse battery member 200 and a reuse product storage device 260. The reuse battery member 200 is a member in which the battery member 100 is reused and includes a reuse battery 220 and a reuse accessory component 240. The reuse battery 220 is a battery that has a similar configuration to the battery 120 and for which the battery 120 degrades. The reuse accessory component 240 is a device which is appropriate for a reuse product and is selected from the reuse accessory components 240 in the battery member 100. For example, when a low-voltage battery is not provided in a robot which is a reuse product, a current sensor, a voltage sensor, a temperature sensor, and the like are provided in the reuse accessory component 240, but a converter is not provided.

Each device included in the reuse battery member 200 operates similarly to each device included in the battery member 100. Therefore, a battery ECU included in the reuse battery member 200 monitors and collects each piece of information regarding a current, a voltage, temperature, and the like of the reuse battery 220 output by each sensor such as a current sensor, a voltage sensor, a temperature sensor, and the like and stores the information as reuse battery use state collection data 262 in the reuse product storage device 260. The battery ECU calculates a SOC or SOH of the reuse battery 220, collects an uptime and elapsed years of the reuse battery member 200, and stores the uptime and the elapsed years in the reuse product storage device 260, as in the battery ECU 145 of the battery member 100.

The reuse product storage device 260 is realized by, for example, a storage device such as an HDD or a flash memory included in the reuse battery member 200. The reuse product storage device 260 stores, for example, the various kinds of information regarding the current, the voltage, the temperature, the SOH, and the like of the reuse battery 220 collected and calculated by the battery ECU of the reuse battery member 200 as the reuse battery use state collection data 262.

FIG. 6 is a diagram showing an example of the reuse battery use state collection data 262. As shown in FIG. 6, the reuse battery use state collection data 262 includes items such as an application, a battery ID, a reuse date, a degradation element, a battery SOH, and a failure date. Of these items, the battery ID, the degradation element, the battery SOH, and the failure date are similar to the items of the battery use state collection data 162.

The item of the application is determined by the reuse product 50. For example, when the reuse product 50 is a robot, the application is “robot.” When the reuse product 50 is a forklift, the application is “forklift.” The reuse date is a date on which the reuse battery 220 is mounted on the reuse product 50.

The battery ECU included in the reuse battery member 200 acquires a degradation state of the reuse battery member 200. The degradation state of the reuse battery member 200 may be collected, for example, from the perspective of two factors of an element during an uptime and an element of a vehicle's lifetime. The degradation state of the reuse battery member 200 may be expressed collectively as in the following (2), for example.

Degradation state of reuse battery 220=f(use environment (accessory component temperature, load), an uptime, elapsed years) (2)

Of these elements, the accessory component temperature and the load are obtained through calculation or the like for each reuse accessory component 240 based on detection results of the current sensor, the voltage sensor, and the temperature sensor serving as each reuse accessory component 240. The uptime and the elapsed years are obtained based on the uptime and the elapsed years of the reuse battery member 200.

The reuse product 50 includes, for example, a reuse product communication device that includes a wireless module for connecting a cellular network or a Wi-Fi network. The battery ECU included in the reuse battery member 200 associates each piece of monitored data with failure of the reuse battery 220 as a database when the reuse battery 220 fails or the reuse battery 220 which has not failed is detached from the reuse product 50. In this way, the battery ECU generates the reuse battery use state collection data 262 and transmits the reuse battery use state collection data 262 shown in FIG. 6 to the reuse product communication device. The reuse product communication device transmits the reuse battery use state collection data 262 such as the current value, the voltage value, the temperature, and the SOH of the reuse battery 220 output by the reuse battery member 200 to the lifetime prediction device 400 via the network NW shown in FIG. 1.

The lifetime prediction device 400 manages the battery member 100 and the reuse battery member 200 by using the battery ID. Therefore, in the lifetime prediction device 400, the series of degradation states from the on-board time to the reuse of the battery member 100 can be managed. Accordingly, even for the reuse product 50, the degradation state of the battery member 100 (the reuse battery member 200) can be appropriately managed.

### [Lifetime Prediction Device 400]

As shown in FIG. 2, the lifetime prediction device 400 includes, for example, a communicator 410, an acquirer 420, a generator 430, a predictor 440, and a storage 470. The acquirer 420, the generator 430, and the predictor 440 are realized, for example, by causing a hardware processor such as a CPU to execute a program. Some or all of the constituent elements may be realized by hardware such as an LSI, an ASIC, an FPGA, or a GPU or may be realized by software and hardware in cooperation. The program may be stored in advance in a storage device such as an HDD or a flash memory or may be stored in a detachably mountable storage medium such as a DVD, a CD-ROM, or the like so that the storage medium is mounted on a drive device to be installed. The storage 470 is realized by the above-described storage device. The lifetime prediction device 400 manages the battery member and the reuse battery member 200 based on the information transmitted by the vehicle 10 and the reuse product 50 and predicts a lifetime of the reuse battery member 200.

The communicator 410 includes a wireless module for connecting a cellular network or a Wi-Fi network in accordance with an instruction of the acquirer 420. The communicator 410 receives the battery use state collection data 162 transmitted by the vehicle 10 and the reuse battery use state collection data 262 transmitted by the reuse produce 50.

The communicator 410 is considered to communicate with the plurality of vehicles 10 and the plurality of reuse products 50. The communicator 410 receives the battery use state collection data 162 and the reuse battery use state collection data 262 transmitted by the pluralities of (many) vehicles 10 and reuse products 50. Therefore, the lifetime prediction device 400 receives the massive battery use state collection data 162 and reuse battery use state collection data 262.

The acquirer 420 acquires the battery use state collection data 162 transmitted by the vehicles 10 and the reuse battery use state collection data 262 transmitted by the reuse products 50 by causing the communicator 410 to receive the battery use state collection data 162 and the reuse battery use state collection data 262. The acquirer 420 stores the acquired battery use state collection data 162 and reuse battery use state collection data 262 in the storage 470.

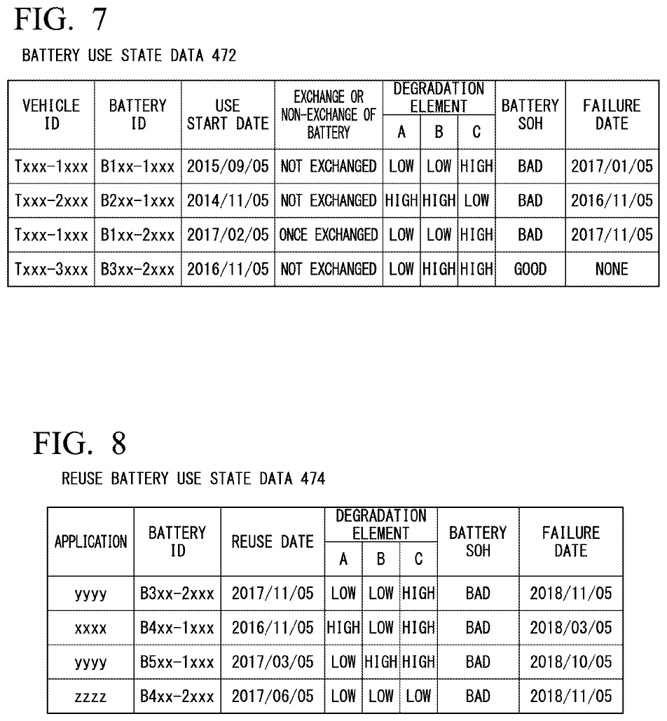

The acquirer 420 collects the plurality of pieces of battery use state collection data 162 transmitted by the plurality of vehicles 10 and generates and acquires battery use state data 472. FIG. 7 is a diagram showing an example of the battery use state data 472. The battery use state data 472 is data in which the battery use state collection data 162 transmitted by the plurality of vehicles 10 are arranged in order in which the communicator 410 receives the battery use state collection data 162.

The acquirer 420 collects the plurality of pieces of reuse battery use state collection data 262 transmitted by the plurality of reuse products 50 and generates and acquires reuse battery use state data 474. FIG. 8 is a diagram showing an example of the reuse battery use state data 474. The reuse battery use state data 474 is data in which the reuse battery use state collection data 262 transmitted by the plurality of reuse products 50 are arranged in order in which the communicator 410 receives the reuse battery use state collection data 262.

The generator 430 performs machine learning using the battery use state data 472 and the reuse battery use state data 474 received by the communicator 410 and stored in the storage 470 as learned data and supervised data to generate a lifetime prediction model 476. The generator 430 generates a neural network model of the pluralities of vehicles 10 and reuse products 50 as the lifetime prediction model 476 by using data acquired from the battery use state data 472 and the reuse battery use state data 474 as input data and using a lifetime of the reuse battery member 200 as output data.

The generator 430 generates the lifetime prediction model 476 by using input data of the neural network model as a use state of the battery member 100, exchange or non-exchange of a battery of the battery member 100, a use period of the battery member 100, a use of the reuse battery member 200, a use state of the reuse battery member 200, and the lifetime of the reuse battery member 200 and using output data as the lifetime of the reuse battery member 200. The generator 430 stores the generated lifetime prediction model 476 in the storage 470. The generator 430 may generate the lifetime prediction model 476 by limiting input data input to an input layer in the embodiment to some of the data. In particular, the generator 430 may generate the lifetime prediction model 476 by limiting the use state to some items. The generator 430 may generates the lifetime prediction model 476 classified for each piece of data input to the input layer. For example, the generator 430 may generate the lifetime prediction model 476 for each use (type of reuse product 50) of the reuse battery member 200. The generator 430 may generate the lifetime prediction model 476 by associating a degradation element with the SOH of the battery 120.

The predictor 440 predicts a lifetime, for example, when the battery member 100 is detached from the vehicle 10 or a reuse product manufacturer makes a lifetime prediction request and the battery member 100 is reused at the time of reuse as the reuse battery member 200. The lifetime prediction request may be made, for example, specifying the prediction target battery member 100 (the battery member 100 before the battery member 100 is reused as the reuse battery member 200) or may be made by setting some or all of the battery members 100 managed by the lifetime prediction device 400 as prediction targets. The predictor 440 may predict the lifetime of the reuse battery member 200 in accordance with a rule base based on each piece of data input to the input layer of the lifetime prediction model 476 without using the lifetime prediction model 476.

When the lifetime of the reuse battery member 200 is predicted, the predictor 440 acquires the battery use state data 472 of the battery member 100 before the battery member 100 is reused as the reuse battery member 200 which is a prediction target, and reads the lifetime prediction model 476 from the storage 470. The predictor 440 predicts the lifetime of the reuse battery member 200 based on the battery use state data 472 and the lifetime prediction model 476. The predictor 440 uses the communicator 410 to transmit information regarding the predicted lifetime of the reuse battery member 200 to the reuse product manufacturer having made the lifetime prediction request.

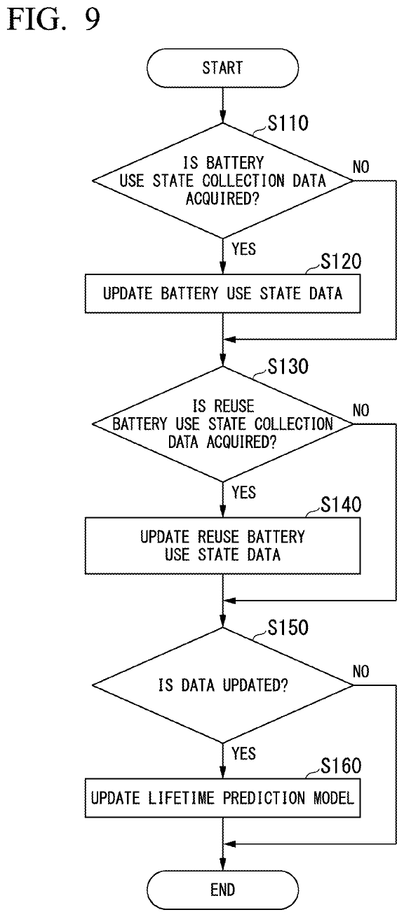

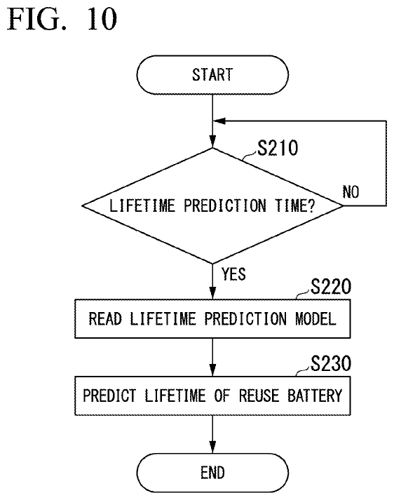

Next, a process in the lifetime prediction device 400 will be described. FIGS. 9 and 10 are flowcharts showing an example of a flow of a process performed in the lifetime prediction device 400. Here, a process of updating the lifetime prediction model 476 will first be described with reference to FIG. 9. Next, a process of predicting a lifetime of the reuse battery member 200 will be described with reference to FIG. 10. As shown in FIG. 9, the acquirer 420 determines whether to acquire the battery use state collection data 162 (step S110).

When the acquirer 420 determines to acquire the battery use state collection data 162, the acquirer 420 reads the battery use state data 472 from the storage 470 and adds the acquired battery use state collection data 162 to the battery use state data 472 to update the battery use state data 472 (step S120). When the acquirer 420 determines not to acquire the battery use state collection data 162, the lifetime prediction device 400 causes the process to proceed to step S130.

Subsequently, the acquirer 420 determines whether to acquire the reuse battery use state collection data 262 (step S130). When the acquirer 420 determines to acquire the reuse battery use state collection data 262, the acquirer 420 reads the reuse battery use state data 474 from the storage 470 and adds the acquired reuse battery use state collection data 262 to the reuse battery use state data 474 to update the reuse battery use state data 474 (step S140). When the acquirer 420 determines not to acquire the reuse battery use state collection data 262, the lifetime prediction device 400 causes the process to proceed to step S150.

Subsequently, the generator 430 determines whether the battery use state collection data 162 or the reuse battery use state collection data 262 is updated (step S150). When the generator 430 determines that the data is updated, the generator 430 reads the lifetime prediction model 476 from the storage 470 and updates the lifetime prediction model 476 based on the updated data or the like (step S160).

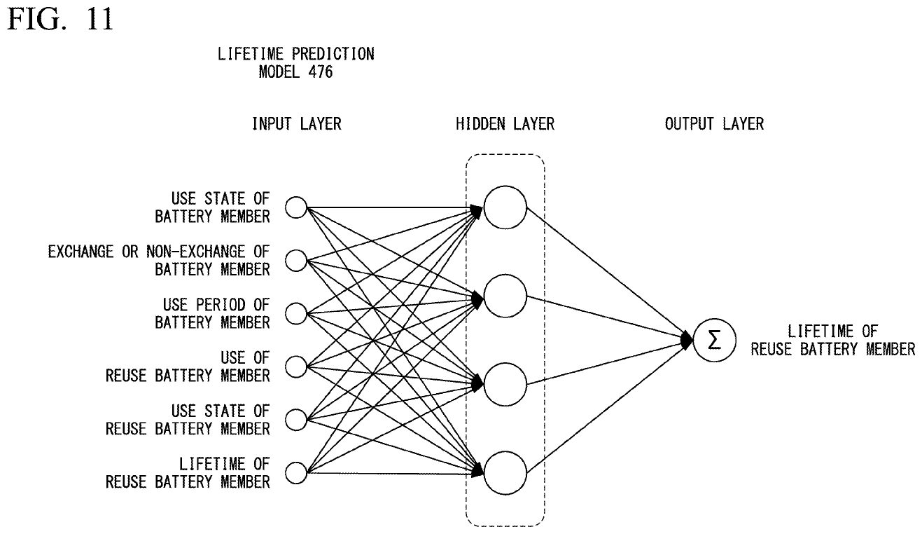

FIG. 11 is a conceptual diagram showing an example of a production process of the lifetime prediction model 476. As shown in FIG. 11, the generator 430 generates the lifetime prediction model 476 that has an input layer, a hidden layer, and an output layer. A use state of the battery member 100, exchange or non-exchange of the battery member 100, a use period of the battery member 100, a use of the reuse battery member 200, a use state of the reuse battery member 200, and a lifetime of the reuse battery member 200 are input to the input layer. The use period of the battery member 100 is period from a use start date of the battery member 100 to a failure occurrence date or a date on which failure does not occur and the battery member 100 is detached from a vehicle for exchange. The lifetime of the reuse battery member 200 is a period from a reuse date of the reuse battery member 200 to a failure occurrence date.

The lifetime of the reuse battery member 200 is output to the output layer. The hidden layer has a neural network of multiple layers connecting the input layer and the output layer. Parameters of the hidden layer are optimized by performing machine learning using an input to the input layer as input data and output data output from the output layer. The generator 430 updates (generates) the lifetime prediction model 476 in this way.

Referring back to the flowchart shown in FIG. 9, the generator 430 stores the updated lifetime prediction model 476 in the storage 470 (step S170). In this way, the lifetime prediction device 400 updates the lifetime prediction model 476 and then ends the process shown in FIG. 9. Further, in step S150, when it is determined that the data is not updated, the lifetime prediction device 400 ends the process shown in FIG. 9 without continuing the process.

Subsequently, the process of predicting the lifetime of the reuse battery member 200 will be described with reference to FIG. 10. The predictor 440 determines whether the present time is a lifetime prediction time (step S210). When information regarding detachment of the battery member 100 from the vehicle 10 is acquired or and a lifetime prediction request sent by a reuse product manufacturer or the like is received by the communicator 410, the predictor 440 determines that the present time is the lifetime prediction period.

When it is determined that the present time is not the lifetime prediction time, the lifetime prediction device 400 ends the process shown in FIG. 10 without continuing the process. When the predictor 440 determines that the present time is the lifetime prediction time, the predictor 440 reads the lifetime prediction model 476 from the storage 470 (step S220). Subsequently, the lifetime of the reuse battery member 200 is predicted using the use state of the battery member 100 reused as the reuse battery member 200 which is a prediction target and the lifetime prediction model 476 (step S230). At this time, information regarding the use of the reuse battery member may be further used. In this way, the lifetime prediction device 400 ends the process shown in FIG. 10.

According to the above-described embodiment, the lifetime of the reuse battery member 200 reused from the battery member 100 is predicted based on the information regarding the reuse battery member 200, such as the use, the use state, and the lifetime of the reuse battery member 200. Therefore, for example, since the information regarding the predicted lifetime of the reuse battery member 200 can be supplied, for example, without mounting the reuse battery on a latest use product and newly carrying out an endurance test, a standard for selecting a battery member to be reused can be provided.

In the foregoing embodiment, with regard to the battery member 100 detached from the vehicle 10, the lifetime of the reuse battery member 200 reused from the battery member 100 is predicted. However, with regard to the battery member 100 mounted on the vehicle 10, a lifetime of the reuse battery member 200 reused from the battery member 100 may be predicted. In this case, since a use state of the battery member 100 when the battery member 100 is detached from the vehicle 10 is unknown, for example, the use state of the battery member 100 at a predetermined time at which the battery member 100 is detached may be estimated based on the use state of the battery member 100 mounted on the vehicle 10 and the lifetime of the reuse battery member 200 may be predicted from the estimated use state of the battery member 100. In this case, a plurality of times at which the battery member 100 is detached may be assumed and the lifetime of the reuse battery member 200 at each time may be predicted.

In the foregoing embodiment, the use state of the battery member 100 is stored in the vehicle storage device 160 mounted on the vehicle 10 and is collected and transmitted as the battery use state collection data 162 to the lifetime prediction device 400. However, individual data of the use state of the battery member 100 may be transmitted to the lifetime prediction device 400, another server, or the like and the battery use state collection data 162 may be generated at a transmission destination. Similarly, the reuse battery use state collection data 262 may also be generated by the lifetime prediction device 400, another server, or the like instead of being collected in the reuse product 50. The vehicle 10 or the reuse product 50 may have each function of the generator 430 or the predictor 440 in the lifetime prediction device 400.

In the foregoing embodiment, the lifetime of the reuse battery member 200 with respect to the entire battery member 100 is predicted. However, a lifetime of only the battery 120 in the battery member 100 or a reuse product of each accessory component 140 may be predicted. In this case, for example, a lifetime prediction model may be generated for each reuse product and a lifetime of the reuse product may be predicted. A lifetime of an individual reuse product may be predicted or a collective lifetime of some of a plurality of reuse products may be predicted.

The embodiments for carrying out the present invention have been described above, but the present invention is not limited to the embodiments. Various modifications and substitutions can be made within the scope of the present invention without departing from the gist of the present invention.

What is claimed is:

1. A lifetime prediction device comprising:
an acquirer configured to acquire information regarding a use state of a battery member mounted on a vehicle; and
a predictor configured to predict a lifetime of the battery member to be reused at the time of reuse according to the use state.

2. The lifetime prediction device according to claim 1, wherein the predictor is configured to predict the lifetime according to a type of a target product in which the battery member is reused.

3. The lifetime prediction device according to claim 1,
wherein the acquirer is configured to acquire information regarding a use state at the time of reuse of the battery member, and
wherein the predictor is configured to predict the lifetime according to the information regarding the use state at the time of reuse of the battery member.

4. The lifetime prediction device according to claim 1 wherein the information regarding the use state of the battery member is information according to information collected in the vehicle.

5. The lifetime prediction device according to claim 1, wherein the battery member includes at least one of a battery or an accessory component of the battery.

6. The lifetime prediction device according to claim 5, wherein the accessory component includes at least one of a cooling fan, a current sensor, a voltage sensor, a temperature sensor, a battery calculation device, a contactor, a converter, or a fuse.

7. The lifetime prediction device according to claim 1, wherein the predictor is configured to predict the lifetime by inputting information regarding a use state of the battery member to a model obtained through machine learning.

8. The lifetime prediction device according to claim 7, further comprising:
a generator configured to generate the model through machine learning.

9. A lifetime prediction method using a computer, comprising:
to acquiring information regarding a use state of a battery member mounted on a vehicle; and
to predicting a lifetime of the battery member to be reused at the time of reuse according to the use state.

10. A computer-readable non-transitory storage medium that stores a program causing a computer:
to acquire information regarding a use state of a battery member mounted on a vehicle; and
to predict a lifetime of the battery member to be reused at the time of reuse according to the use state.
